(19) United States
(12) Patent Application Publication
(10) Pub. No.: US 2026/0129984 A1
(43) Pub. Date: May 7, 2026

(54) HIGH QUANTUM EFFICIENCY AND HIGHLY STABLE BACKSIDE-ILLUMINATED IMAGE SENSORS

(71) Applicant: TELEDYNE DIGITAL IMAGING, INC., Toronto (CA)

(72) Inventor: Hyun Jung Lee, Waterloo (CA)

(21) Appl. No.: 19/377,502

(22) Filed: Nov. 3, 2025

Related U.S. Application Data
(60) Provisional application No. 63/715,935, filed on Nov. 4, 2024.

(51) Int. Cl. H10F 39/12; H10F 39/00

(52) U.S. Cl. CPC H10F 39/199; H10F 39/028

(57) ABSTRACT

High quantum efficiency (QE) and highly stable (back-side illuminated (BSI) image sensors are provided. The BSI image sensors include a first substrate and a high doped, ultra-shallow junction (USJ). The first substrate includes a first side and a second side. The first side includes a plurality of image sensor pixels. The second side includes an at least partially exposed epitaxial layer includes a silicon lattice. The USJ is formed in the epitaxial layer. The USJ is formed by applying a dopant to the epitaxial layer utilizing atomic layer deposition (ALD) or monolayer doping (MLD) and laser annealing the epitaxial layer for drive-in diffusion of the dopant into the epitaxial layer and activation of the dopant in the silicon lattice of the epitaxial layer, thereby forming the USJ.

### CROSS-REFERENCE

The present application claims priority to U.S. Provisional Application No. 63/715,935, filed Nov. 4, 2024. The entire contents of which is hereby incorporated by reference into this specification.

### FIELD

This disclosure relates to backside-illuminated image sensors and more particularly relates to high quantum efficiency (QE) and highly stable back-side illuminated (BSI) image sensors.

### BACKGROUND

Back-side illuminated (BSI) sensors are image sensors in which the pixels are positioned closer to the region at which the light enters the sensor than to the metal wiring. The manufacture of BSI sensors presents challenges.

### SUMMARY

Non-limiting aspects of the present disclosure are directed to a BSI image sensor comprising a first substrate and a high doped, ultra-shallow junction (USJ). The first substrate comprises a first side and a second side. The first side comprises a plurality of image sensor pixels. The second side comprises an at least partially exposed epitaxial layer comprising a silicon lattice. The USJ is formed in the epitaxial layer. The USJ is formed by applying a dopant to the epitaxial layer utilizing atomic layer deposition (ALD) or monolayer doping (MLD) and laser annealing the epitaxial layer for drive-in diffusion of the dopant into the epitaxial layer and activation of the dopant in the silicon lattice of the epitaxial layer, thereby forming the USJ.

Other non-limiting aspects of the present disclosure are directed to a method for forming an USJ on a backside illuminated image sensor. The method comprises applying a dopant to an at least partially exposed epitaxial layer, comprising a silicon lattice, on a side of a first substrate utilizing atomic layer deposition (ALD) or monolayer doping (MLD). The method comprises laser annealing the epitaxial layer for drive-in diffusion of the dopant into the epitaxial layer and activation of the dopant in the silicon lattice of the epitaxial layer, thereby forming the USJ.

It will be understood that the inventions disclosed and described in this specification are not limited to the aspects summarized in this Summary. The reader will appreciate the foregoing details, as well as others, upon considering the following detailed description of various non-limiting and non-exhaustive aspects according to this specification.

### BRIEF DESCRIPTION OF THE FIGURES

The features and advantages of the examples presented herein, and the manner of attaining them, will become more apparent, and the examples will be better understood, by reference to the following description taken in conjunction with the accompanying drawings, wherein:

FIG. 1 illustrates a non-limiting embodiment of a method of forming a BSI image sensor according to the present disclosure;

FIG. 2 provides a graphical depiction of a non-limiting embodiment of formation of a BSI image sensor according to the present disclosure;

FIG. 3 provides a graphical depiction of a non-limiting embodiment of formation of a BSI image sensor according to the present disclosure; and

FIG. 4 provides a graphical depiction of a non-limiting embodiment of formation of a BSI image sensor according to the present disclosure.

The exemplifications set out herein illustrate certain non-limiting embodiments, in one form, and such exemplifications are not to be construed as limiting the scope of the appended claims and the invention in any manner.

### DETAILED DESCRIPTION

Various examples are described and illustrated herein to provide an overall understanding of the structure, function, and use of the disclosed systems, apparatus, and methods. The various examples described and illustrated herein are non-limiting and non-exhaustive. Thus, the invention is not limited by the description of the various non-limiting and non-exhaustive examples disclosed herein. Features and characteristics illustrated and/or described in connection with various examples herein may be combined with features and characteristics of other examples herein. Such modifications and variations are intended to be included within the scope of the present disclosure. The various non-limiting embodiments disclosed and described in the present disclosure can comprise, consist of, or consist essentially of the features and characteristics as variously described herein.

Any references herein to “various non-limiting embodiments”, “some non-limiting embodiments”, “certain non-limiting embodiments”, “one non-limiting embodiment”, “a non-limiting embodiment”, “an embodiment”, “one embodiment”, or like phrases mean that a particular feature, structure, act, or characteristic described in connection with the example is included in at least one embodiment. Thus, appearances of the phrases “various non-limiting embodiments”, “some non-limiting embodiments”, “certain non-limiting embodiments”, “one non-limiting embodiment”, “a non-limiting embodiment”, “an embodiment”, “one embodiment”, or like phrases in the specification do not necessarily refer to the same non-limiting embodiment. Furthermore, the particular described features, structures, or characteristics may be combined in any suitable manner in one or more non-limiting embodiments. Thus, the particular features, structures, or characteristics illustrated or described in connection with one non-limiting embodiment may be combined, in whole or in part, with the features, structures, or characteristics of one or more other non-limiting embodiments without limitation. Such modifications and variations are intended to be included within the scope of the present non-limiting embodiments.

As used herein, “at least one of” a list of elements means one of the elements or any combination of two or more of the listed elements. As an example, “at least one of A, B, and C” means A only; B only; C only; A and B; A and C; B and C; or A, B, and C.

Although, the disclosure relates to different aspects and embodiments, it is understood that the different aspects and embodiments disclosed herein can be integrated, combined, or used together as a combination system, or in part, as separate components, devices, and systems, as appropriate. Thus, each embodiment disclosed herein can be incorporated in each of the aspects to varying degrees as appropriate for a given implementation.

A charge coupled device (CCD) image sensor can comprise pixels arranged in a two-dimensional array. The pixels can trap and hold photon-induced charge carriers. In a CCD image sensor, individual pixels can be separated from each other by voltage applied to surface electrodes in one direction, and channel stops (e.g., insulating barriers within the silicon substrate) in the other direction. The photoactive region of the CCD image sensor can be a p-doped epitaxial layer of silicon. There can be bias gate electrodes within the epitaxial layer and an n-doped channel below the gate electrodes. An insulating silicon dioxide layer can be grown on the epitaxial layer of the silicon substrate. Polycrystalline silicon gates can lie perpendicular to the channels and can be separated from the channels by the silicon dioxide layer.

The epitaxial layer can be a layer of crystalline silicon formed on top of a silicon substrate of the CCD pixel array wafer. The epitaxial layer can comprise silicon purer than silicon of the silicon substrate of the CCD pixel array wafer. The epitaxial layer can enhance electron transfer efficiency and homogeneity of the silicon substrate. In various embodiments, the epitaxial layer can comprise a thickness in a range of 4 μm to 30 um, with a total thickness variation (TTV) of no greater than 0.5 um.

In a complementary metal oxide semiconductor (CMOS) image sensor, each pixel can comprise a photodiode and a metal oxide semiconductor field-effect transistor (MOSFET) switch. A pixel in a CMOS image sensor can comprise a pinned photodiode, a photodetector, and transistors including a transfer gate, reset gate, selection gate, and a source-follower readout transistor, among other components. Each CMOS sensor pixel can comprise its own readout integrated circuit (ROIC) proximal to the photosensitive area.

CMOS image sensors typically can have a digital readout and include a massively parallel data path, which can lead to faster read out speeds than CCD imagers which are typically analog. CCD image sensors can have ultra-high-full well capacity (FWC) and ultra-high sensitivity, which may not be present in CMOS image sensors.

For a balance of CCD and CMOS advantages, CCD-CMOS Time Delayed Integrated TDI (CCD-CMOS TDI) image sensors have been rapidly displacing traditional CCD TDI image sensors in various applications such as, for example, industrial, machine vision, DNA sequencing, and Earth observation.

The formation of surface defects on BSI silicon (Si) image sensors is inevitable due to a lattice mismatch between Si and SiO₂. Charging and discharging the defect states can cause instability in the image sensors, known as a quantum efficiency hysteresis (QEH). Furthermore, performance degradation occurs due to positive oxide charge (i.e., fixed charge near the Si/SiO₂ interface and interface trapped charge at the interface) generated by prolonged ionizing radiation impinging onto the Si surface of the BSI imagers. Even non-ionizing 193 nm deep ultraviolet (DUV) light can break weak Si—H bonds and thus create the trap states at the interface.

Surface passivation is a process performed to generate built-in electric fields that guide signal electrons from the back surface to the front side potential well of the image sensor by forming a highly doped region on the back Si surface. For good imager stability irrespective of the positive oxide charge, the Si surface can be doped highly enough to prevent the Si surface from being depleted by the positive oxide charge. Simultaneously, the formation of an USJ can be performed for high QE, particularly for DUV having a very short absorption depth from the Si surface.

There are several techniques of surface passivation which are summarized in Table 1. The “ion implantation+laser annealing” technique employs ion implantation on the Si surface followed by laser annealing for dopant activation and implantation damage curing. As lattice damage to the Si network by energetic ion bombardment may be unavoidable during ion implantation, Si melting laser annealing (MLA) may be used to cure the implantation damage fully, which can lead to junction formation. Si non-melting laser annealing (NLA) may have an advantage for USJ formation. However, NLA may have a disadvantage of incomplete implantation damage curing. Achieving good implantation uniformity for low energy implant for USJ formation can be challenging due to space-charge beam blow up.

The high-k passivation technique can use negative oxide charge in a high-k material such as HfO₂, Al₂O₃, and Ta₂O₅ for p-type Si passivation. However, the maximum negative fixed charge density achievable reported to date may not be high enough to prevent the Si surface depletion. δ-doping (or superlattice doping), proposed by JPL (U.S. Pat. No. 8,395,243), is based on high Si surface doping using molecular beam epitaxy (MBE), which can provide good stability. However, it may have disadvantages of high process complexity and high cost. Another technique called “pure B” (Sarubbi et al. 2008) forms an α-B/BₓSi₁₋ₓ stack on the Si surface using a B₂H₆ reaction with the Si surface in a chemical vapor deposition (CVD) apparatus, which may provide good stability. However, it may use a high processing temperature (˜700° C.) for the formation of the “pure B” layer, which may not be compatible for conventional CMOS image sensor technology. Thus, known methods to date may not satisfy all the requirements for high QE and highly stable BSI image sensors.

TABLE 1
Surface Passivation Techniques

| | Ion implantation + | | | |
|---|---|---|---|---|
| | Laser | High-k | | |
| Technique | Annealing | Passivation | δ-Doping | Pure B |
| Radiation | Poor | Poor | Good | Good |
| stability | | | | |
| Compatibility | Yes | Yes | Yes | No |
| with CMOS | | | | |
| Process | High | Low | High | Low |
| complexity | | | | |
| Cost | High | Low | High | Low |

The present disclosure relates in part to a method of forming a highly doped, USJ on the surface of BSI image sensors for high QE and high stability under DUV light and ionizing radiation such as extreme ultraviolet (EUV), X-ray, and gamma-ray radiation. A plurality of image sensor pixels can be formed on the first side of a first substrate. The plurality of image sensor pixels can be CCD-type or CMOS-type. Meanwhile, pixel readout circuitry is formed on the first side of a second substrate. The second substrate can also be a bare carrier substrate without any circuitry formed.

An oxide film such as tetraethoxysilane (TEOS) can be deposited on the first side of the first and second substrates, respectively. The first side of the first substrate can then be oxide-oxide bonded to the first side of the second substrate via plasma activation. The second side of the first substrate can be thinned, e.g., using chemical mechanical polishing (CMP), to a desirable thickness.

A highly doped, USJ can be formed on the thinned surface of the first substrate using the MLD technique (Ho et al. 2007), e.g., a dopant-containing monolayer can be formed by self-assembled monolayer (SAM) grafting, followed by laser annealing for dopant drive-in and activation. The ALD of a few nm thick dopant-containing oxide (Kalkofen et al. 2014) can be used alternatively to the MLD technique.

In the MLD processing, the pre-treatment of the thinned Si surface can be performed by an HF dip to remove the native oxide on the surface and to terminate the surface with —H or using a piranha solution (i.e., a mixture of H₂SO₄ and H₂O₂) to terminate the surface —OH. As dopant-bearing molecules such as allylboronic acid pinacol ester for p-type doping or diethyl 1-propylphosphonate for n-type doping, respectively, are covalently bonded e.g., to the H-terminated Si surface via hydrosilylation using solution or gas-phase processing followed by laser annealing for dopant drive-in and activation, increasing the surface —H coverage can increase a doping concentration by MLD.

A dielectric capping layer such as SiO₂ can be coated on the SAM to prevent contamination and dopant out-diffusion to air during the subsequent laser annealing. Alternatively in the ALD processing, an oxide containing B or P such as B₂O₃ or P₂O₅, respectively, can be deposited by ALD onto the pre-treated Si surface, similarly to the MLD case. Due to the instability of B₂O₃ and P₂O₅ films in air, they can be capped in situ with an ALD-grown layer such as Sb₂O₅. Then, the dopants can be driven preferentially into Si and activated by laser annealing.

High doping with a peak dopant concentration greater than 10²⁰ cm⁻³ can be achieved using the disclosed technology, which can exceed the solid solubility limit in Si. The disclosed method can form an USJ of less than 5 nm because it can be free from lattice damage and thus free from transient-enhanced diffusion (TED) during annealing. The high doping and USJ achieved by the present disclosure can improve QE and imager stability under DUV and ionizing radiation. The deposition techniques used can be highly-uniform and may not involve high-temperature and high-cost processing.

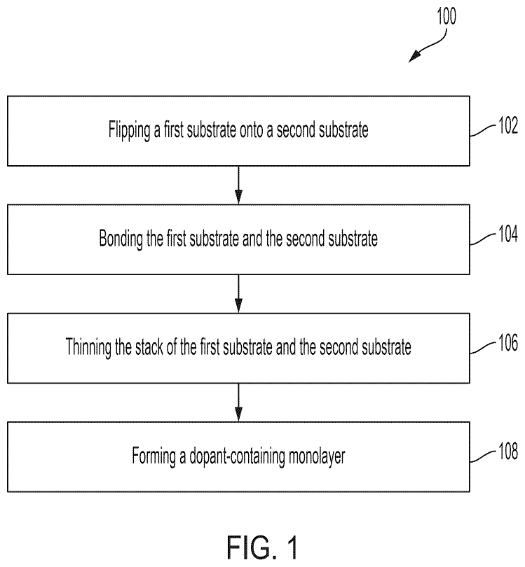

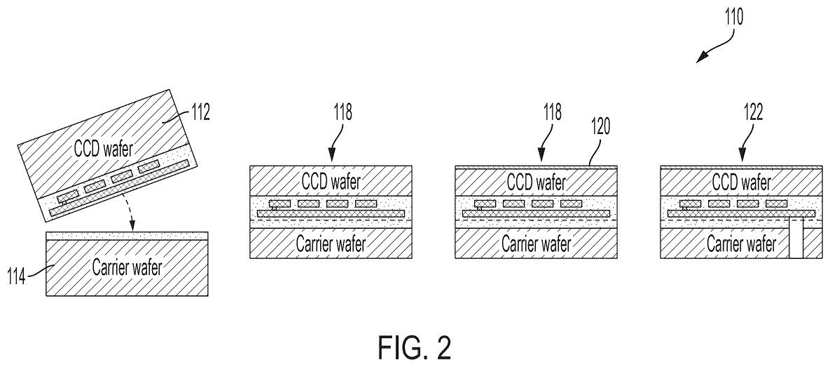

With reference now to the figures, FIG. 1 illustrates aspects of a non-limiting embodiment of a backside thinning process 100 according to the present disclosure. FIG. 2 is a graphical depiction 110 of the backside thinning process of FIG. 1.

The backside thinning process 100 can form a backside illuminated (BSI) image sensor 122. The backside thinning process 100 provides a first substrate 112 and a second substrate 114. The first substrate 112 can be flipped 102 onto the second substrate 114. For example, the first side of the first substrate 112 can be flipped onto the first side of the second substrate 114. The first substrate 112 and second substrate 114 can be bonded 104 together to form a stack. The first substrate 112 may be a CCD wafer or a CMOS-type image sensor. The second substrate 114 may be a carrier wafer without any circuitry formed thereon, or the second substrate 114 may have pixel readout circuitry.

In various non-limiting embodiments, an oxide film can be deposited on the first side of the first substrate 112 and second substrate 114 to form an oxide-oxide bond.

The stack can be then thinned 106 to form a thinned stack 118. Image sensors can be thinned from the back-side (second side of the first substrate 112 and second substrate 114) so that they can be highly sensitive to radiation impinging on the back-side of the image sensors (e.g., these image sensors are back illuminated). At least one of the second sides of the first substrate 112 and second substrate 114 can be thinned. As shown in FIG. 2, the second side of the first substrate 112 and the second substrate 114 are thinned.

Thinning the wafer from the back-side can expose the epitaxial layer 120 in, at least, the active sensor areas. Thinning 106 may involve polishing, etching, or both. In certain non-limiting embodiments, the entire wafer is back-thinned. In various non-limiting embodiments, only the active sensor areas are thinned all the way to the epitaxial layer 120. Methods for thinning 106 include, for example, mechanical grinding, chemical-mechanical planarization (CMP), wet etching, and atmospheric downstream plasma (ADP) with dry chemical etching (DCE).

The backside thinning process 100 may comprise doping 108 the thinned stack 118. Doping can occur through the processes of MLD of ALD. A highly doped, USJ can be formed on the thinned surface of the first substrate using the MLD technique, e.g., a dopant-containing monolayer is formed by self-assembled monolayer (SAM) grafting, followed by laser annealing for dopant drive-in and activation. The ALD of a few nm thick dopant-containing oxide can be used alternatively to the MLD technique. The thinned stack 118 can be doped 108 with dopants to form a BSI image sensor 122.

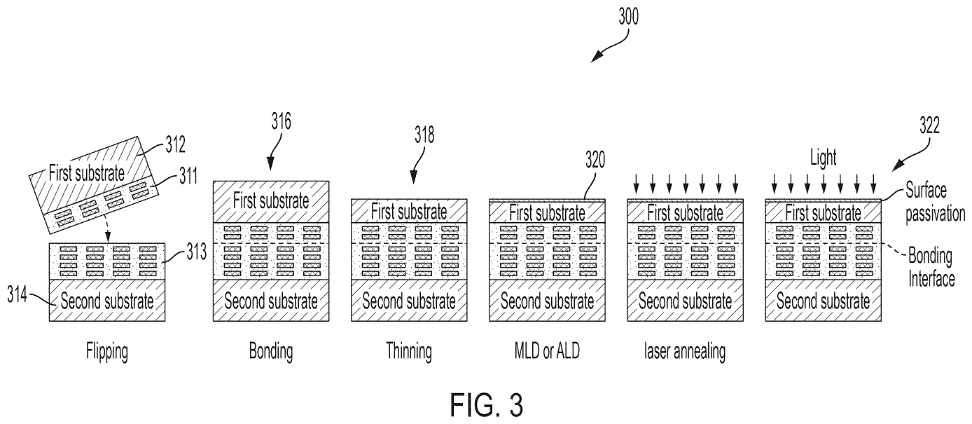

FIG. 3 illustrates aspects of a non-limiting embodiment of a method 300 of forming a BSI image sensor according to the present disclosure. The first substrate 312 can be flipped onto the second substrate 314. The first substrate 312 can have a first side. The first side of the first substrate 312 can have a plurality of image sensor pixels 311. The first side of the second substrate 314 can have pixel readout circuitry 313. The first side of the first substrate 312 and second substrate 314 can comprise an oxide film. The first oxide film can be bonded to the second oxide film to form an oxide-oxide bond. The formation of this bond may be done via plasma activation.

The stack 316 can be thinned to form a thinned stack 318. The thinned stack 318 may be thinned on the second side of the first substrate, as shown in FIG. 3. Thinning the second side of the first substrate 312 can expose the epitaxial layer 320. The thinned stack can be processed via MLD or ALD to form a highly doped, USJ on the second surface of the first substrate 312.

The thinned stack 318 can be doped by laser annealing for dopant drive in and activation. Light can be used for laser annealing. Annealing can be a heat-treatment used to restore disordered semiconductor wafers to crystalline states, after selected “dopant” impurities have been implanted into the wafers (as energetic ions) to adjust the electrical conductivity. Laser annealing can be used to activate the implanted ions. Annealing temperature and time can be selected as desired.

The thinned stack 318 can be subject to dopant drive-in processes. Dopant drive-in can be a process where the dopant is absorbed onto the silicon surface and is driven in by one of three possible steps: activation, diffusion, or regrowth of an oxide, which can provide thermal energy for diffusion. In various non-limiting embodiments, dopant drive-in can be accomplished by laser annealing.

The resultant stack from MLD and annealing can be a backside illuminated sensor 322.

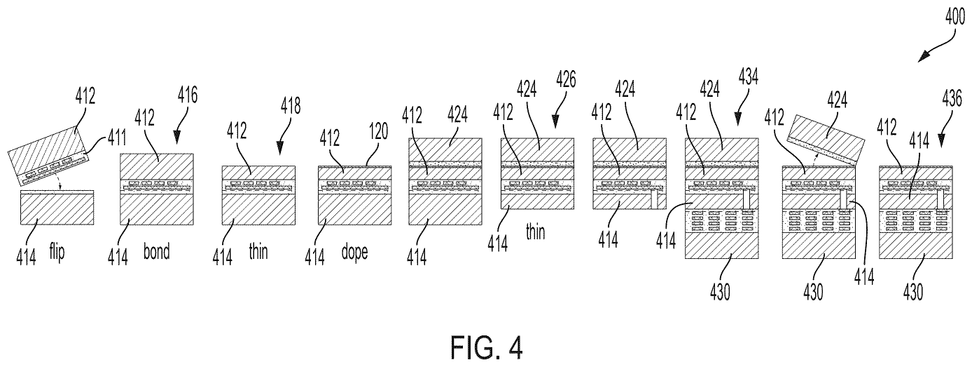

FIG. 4 illustrates aspects of a non-limiting embodiment of a method 400 of forming a BSI image sensor. A CCD wafer 412 can be flipped onto a first carrier wafer 414. The CCD wafer 412 has a first side that comprises a plurality of image sensor pixels 411. The first carrier wafer 414 can be a bare carrier substrate. The first carrier wafer 414 may comprise pixel read out circuitry in some aspects. The CCD wafer 412 bonds with the first carrier wafer 414 to form a stack 416. The stack 416 can be thinned to form a thinned stack 418. As shown, the stack 416 can be thinned on the second side of the CCD wafer 412. In various non-limiting embodiments, the first carrier wafer 414 may be thinned on the second side.

A second carrier wafer 424 can be bonded to the second side of the CCD wafer 412 to form a stack. The first carrier wafer 414 can be thinned from the second side to form a stack 426.

A CMOS wafer 430 can be bonded to the second side of the first carrier wafer 414. The second carrier wafer 424 can be subsequently removed to form a BSI image sensor 436.

Various aspects of non-limiting embodiments according to the present disclosure include, but are not limited to, the aspects listed in the following numbered clauses.

Clause 1. A backside-illuminated (BSI) image sensor comprising: a first substrate comprising a first side and a second side, wherein the second side comprises an at least partially exposed epitaxial layer comprising a silicon lattice, and the first side comprises a plurality of image sensor pixels; and a highly doped, ultra-shallow junction (USJ) formed in the epitaxial layer; wherein the USJ is formed by applying a dopant to the epitaxial layer utilizing atomic layer deposition (ALD) or monolayer doping (MLD), and laser annealing the epitaxial layer for drive-in diffusion of the dopant into the epitaxial layer and activation of the dopant in the silicon lattice of the epitaxial layer, thereby forming the USJ.

Clause 2. The image sensor of clause 1, wherein the dopant is applied to the epitaxial layer by atomic layer deposition (ALD) of a dopant-containing oxide.

Clause 3. The image sensor of clause 2, wherein the epitaxial layer is a —H or —OH terminated silicon surface.

Clause 4. The image sensor of any of clauses 2-3, further comprising a dielectric capping layer on top of the at least partially exposed epitaxial layer such that dopant diffusion during the laser annealing occurs preferentially into silicon, rather than out to air.

Clause 5. The image sensor of any of clauses 1-4, wherein the dopant is applied to the epitaxial layer by a monolayer doping (MLD) technique.

Clause 6. The image sensor of clause 5, wherein the epitaxial layer is a —H or —OH terminated silicon surface.

Clause 7. The image sensor of any of clauses 5-6, further comprising a dielectric capping layer on top of the at least partially exposed epitaxial layer such that dopant diffusion during the laser annealing occurs preferentially into silicon, rather than out to air.

Clause 8. The image sensor of any of clauses 1-7, further comprising a second substrate comprising a third side bonded to the first side of the first substrate, the third side comprising pixel readout circuitry.

Clause 9. A method for forming an ultra shallow junction (USJ) on a backside illuminated image sensor, the method comprising: applying a dopant to an at least partially exposed epitaxial layer, comprising a silicon lattice, on a side of a first substrate utilizing atomic layer deposition (ALD) or monolayer doping (MLD); and laser annealing the epitaxial layer for drive-in diffusion of the dopant into the epitaxial layer and activation of the dopant in the silicon lattice of the epitaxial layer, thereby forming the USJ.

Clause 10. The method of clause 9, wherein the backside illuminated image sensor is formed by: flipping the first substrate onto a second substrate; and bonding the first substrate to the second substrate.

Clause 11. The method of any of clauses 9-10, further comprising applying the dopant to the epitaxial layer utilizing MLD.

Clause 12. The method of any of clauses 9-11, further comprising forming a hydrogen-terminated silicon surface by applying a surface treatment to the epitaxial layer.

Clause 13. The method of any of clauses 9-12, further comprising applying the dopant to the epitaxial layer utilizing ALD.

Clause 14. The method of clause 13, further comprising applying a dielectric capping layer in situ with dopant containing oxides.

Clause 15. The method of any of clauses 11-14, further comprising applying a dielectric capping layer on top of the epitaxial layer.

Clause 16. A backside-illuminated (BSI) image sensor comprising: a first substrate comprising a first side and a second side, wherein the second side is thinned to form a thinned Si surface; a plurality of image sensor pixels formed on the first side of the first substrate; a second substrate comprising a third side and a fourth side; pixel readout circuitry formed on the third side of the second substrate, wherein the first side of the first substrate is bonded to the third side of the second substrate; and a highly doped, ultra-shallow junction (USJ) formed on the thinned surface of the first substrate, wherein the USJ is laser annealed for dopant drive-in and activation.

Clause 17. The image sensor of clause 16, wherein the forming of the USJ uses atomic layer deposition (ALD) of a dopant-containing oxide.

Clause 18. The image sensor of clause 16, wherein the forming of the USJ uses monolayer doping (MLD) technique.

Clause 19. The image sensor of any of clauses 16-18, further comprising pre-treating the thinned Si surface to maximize the surface —H or —OH coverage to maximize a doping concentration by MLD.

Clause 20. The image sensor of any of clauses 16-19, forming a dielectric capping layer so that dopant diffusion during the subsequent laser annealing occurs preferentially into Si, rather than out to air.

Clause 21. The image sensor of clause 17, further comprising pre-treating the thinned Si surface to maximize the surface —H or —OH coverage to maximize a doping concentration by a dopant-bearing oxide.

Clause 22. The image sensor of clause 17, forming a dielectric capping layer in situ with the dopant-containing oxide, so that dopant diffusion occurs preferentially into Si, rather than out to air.

Clause 23. A backside-illuminated (BSI) image sensor comprising: a first substrate comprising: a plurality of image sensor pixels on a first side of the first substrate; an epitaxial layer on a second side of the first substrate; a second substrate bonded to the first side of the first substrate; and an ultra shallow junction (USJ) formed on the second surface of the first substrate.

Clause 24. The image sensor of clause 23, wherein pixel readout circuitry is formed on a first side of a second substrate.

Clause 25. The image sensor of any of clauses 23-24, wherein the second side of the first substrate is thinned to form a thinned surface.

Clause 26. The image sensor of clause 25, wherein the USJ is formed on the thinned surface of the first substrate followed by laser annealing for dopant drive-in and activation.

Clause 27. The image sensor of any of clauses 23-26, wherein the forming of the USJ uses atomic layer deposition (ALD) of a dopant-containing oxide.

Clause 28. The image sensor of any of clauses 23-26, wherein the forming of the USJ uses monolayer doping (MLD) technique.

Clause 29. A method comprising: forming a dopant-containing monolayer onto a silicon surface of a backside illuminated imager; and laser annealing for dopant drive-in and activation.

Clause 30. The method of clause 29, wherein the backside illuminated imager is formed by: flipping a first substrate onto a second substrate; and bonding the first substrate to the second substrate.

Clause 31. The method of any of clauses 29-30, wherein forming a dopant-containing monolayer comprises monolayer doping the silicon surface.

Clause 32. The method of clause 31, further comprising treating the silicon surface with a surface treatment to expose a hydrogen-terminated silicon surface.

Clause 33. The method of clause 32, further comprising doping the silicon surface with dopant-bearing molecules.

Clause 34. The method of any of clauses 29-30, wherein forming a dopant-containing monolayer comprises atomic layer deposition to the silicon surface.

Clause 35. The method of clause 34, further comprising capping oxides with an atomic deposition layer.

In the present disclosure, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Also, any numerical range recited herein includes all sub-ranges subsumed within the recited range. For example, a range of “1 to 10” includes all sub-ranges between (and including) the recited minimum value of 1 and the recited maximum value of 10, that is, having a minimum value equal to or greater than 1 and a maximum value equal to or less than 10. Any maximum numerical limitation recited in this specification is intended to include all lower numerical limitations subsumed therein, and any minimum numerical limitation recited in the present disclosure is intended to include all higher numerical limitations subsumed therein. Accordingly, Applicant reserves the right to amend the present disclosure, including the claims, to expressly recite any sub-range subsumed within the ranges expressly recited. All such ranges are inherently described in the present disclosure.

The grammatical articles “a,” “an,” and “the,” as used herein, are intended to include “at least one” or “one or more,” unless otherwise indicated, even if “at least one” or “one or more” is expressly used in certain instances. Thus, the foregoing grammatical articles are used herein to refer to one or more than one (i.e., to “at least one”) of the particular identified elements. Further, the use of a singular noun includes the plural, and the use of a plural noun includes the singular, unless the context of the usage requires otherwise.

The foregoing detailed description has set forth various forms of the devices and/or processes via the use of schematic illustrations and examples. Insofar as such schematics and examples include functions and/or operations, it will be understood by those skilled in the art that each function and/or operation in such schematics and examples can be implemented, individually and/or collectively, by a wide range of hardware, software, firmware, or virtually any combination thereof. Those skilled in the art will recognize that some examples of the forms disclosed herein, in whole or in part, may be equivalently implemented in integrated circuits, as a computer program running on a computer (e.g., as a programs running on a computer system), as a program running on a processor (e.g., as a program running on a microprocessor), as firmware, or as virtually any combination thereof, and that designing the circuitry and/or writing the code for the software and or firmware would be well within the skill of one skilled in the art in light of this disclosure. In addition, those skilled in the art will appreciate that the mechanisms of the subject matter described herein are capable of being distributed as a program product in a variety of forms, and an illustrative form of the subject matter described herein applies regardless of the particular type of signal-bearing medium used to actually carry out the distribution.

One skilled in the art will recognize that the herein described apparatus, systems, structures, methods, operations/actions, and objects, and the discussion accompanying them, are used as examples for the sake of conceptual clarity and that various configuration modifications are contemplated. Consequently, as used herein, the specific examples/embodiments set forth and the accompanying discussion are intended to be representative of their more general classes. In general, use of any specific exemplar is intended to be representative of its class and the non-inclusion of specific components, devices, apparatus, operations/actions, and objects should not be taken as limiting. While the present disclosure provides descriptions of various specific aspects for the purpose of illustrating various aspects of the present disclosure and/or its potential applications, it is understood that variations and modifications will occur to those skilled in the art. Accordingly, the invention or inventions described herein should be understood to be at least as broad as they are claimed and not as more narrowly defined by particular illustrative aspects provided herein.

1. A backside-illuminated (BSI) image sensor comprising:
a first substrate comprising a first side and a second side, wherein the first side comprises a plurality of image sensor pixels, and the second side comprises an at least partially exposed epitaxial layer comprising a silicon lattice; and
a highly doped, ultra-shallow junction (USJ) formed in the epitaxial layer, wherein the USJ is formed by
applying a dopant to the epitaxial layer utilizing atomic layer deposition (ALD) or monolayer doping (MLD); and
laser annealing the epitaxial layer for drive-in diffusion of the dopant into the epitaxial layer and activation of the dopant in the silicon lattice of the epitaxial layer, thereby forming the USJ.

2. The image sensor of claim 1, wherein the dopant is applied to the epitaxial layer by atomic layer deposition (ALD) of a dopant-containing oxide.

3. The image sensor of claim 2, wherein the epitaxial layer is a —H or —OH terminated silicon surface.

4. The image sensor of claim 2, further comprising a dielectric capping layer on top of the at least partially exposed epitaxial layer such that dopant diffusion during the laser annealing occurs preferentially into silicon, rather than out to air.

5. The image sensor of claim 1, wherein the dopant is applied to the epitaxial layer by a monolayer doping (MLD) technique.

6. The image sensor of claim 5, wherein the epitaxial layer is a —H or —OH terminated silicon surface.

7. The image sensor of claim 5, further comprising a dielectric capping layer on top of the at least partially exposed epitaxial layer such that dopant diffusion during the laser annealing occurs preferentially into silicon, rather than out to air.

8. The image sensor of claim 1, further comprising a second substrate comprising a third side bonded to the first side of the first substrate, the third side comprising pixel readout circuitry.

9. A method for forming an ultra shallow junction on a backside illuminated image sensor, the method comprising:
applying a dopant to an at least partially exposed epitaxial layer, comprising a silicon lattice, on a side of a first substrate utilizing atomic layer deposition (ALD) or monolayer doping (MLD); and
laser annealing the epitaxial layer for drive-in diffusion of the dopant into the epitaxial layer and activation of the dopant in the silicon lattice of the epitaxial layer, thereby forming the USJ.

10. The method of claim 9, wherein the backside illuminated image sensor is formed by:
flipping the first substrate onto a second substrate; and
bonding the first substrate to the second substrate.

11. The method of claim 9, further comprising applying the dopant to the epitaxial layer utilizing MLD.

12. The method of claim 9, further comprising forming a hydrogen-terminated silicon surface by applying a surface treatment to the epitaxial layer.

13. The method of claim 9, further comprising applying the dopant to the epitaxial layer utilizing ALD.

14. The method of claim 13, further comprising applying a dielectric capping layer in situ with dopant containing oxides.

15. The method of claim 11, further comprising applying a dielectric capping layer on top of the epitaxial layer.
